(19) United States
(12) Patent Application Publication
(10) Pub. No.: US 2020/0266161 A1
(43) Pub. Date: Aug. 20, 2020

(54) DETACHABLE BONDING STRUCTURE AND METHOD OF FORMING THEREOF

(71) Applicant: MIKRO MESA TECHNOLOGY CO., LTD., Apia (WS)

(72) Inventors: Li-Yi CHEN, Tainan City (TW); Yi-Ching LIN, Tainan City (TW)

(21) Appl. No.: 16/276,637

(22) Filed: Feb. 15, 2019

(51) Int. Cl. H01L 23/00; H01L 21/18; B32B 7/12

(52) U.S. Cl. CPC H01L 24/05; B32B 7/12; H01L 21/187

(57) ABSTRACT

A detachable bonding structure for performing a device picked-up operation is provided. The detachable bonding structure includes a carrier substrate, a composite glue layer, a metal layer, and a device. The composite glue layer is present on the carrier substrate. The composite glue layer includes an ultraviolet glue and a photolysis material therein. The metal layer is present on the composite glue layer. The device is present on the metal layer.

### BACKGROUND

### Field of Invention

The present disclosure relates to a bonding structure.

### Description of Related Art

The statements in this section merely provide background information related to the present disclosure and do not necessarily constitute prior art.

In recent years, micro devices have become popular in various applications. Among all technical aspects of micro devices, one of the important issues is transferring the micro devices.

### SUMMARY

According to some embodiments of the present disclosure, a detachable bonding structure for performing a device picked-up operation is provided. The detachable bonding structure includes a carrier substrate, a composite glue layer, a metal layer, and a device. The composite glue layer is present on the carrier substrate. The composite glue layer includes an ultraviolet glue and a photolysis material therein. The metal layer is present on the composite glue layer. The device is present on the metal layer.

According to some embodiments of the present disclosure, a method of forming a detachable bonding structure for performing a device picked-up operation is provided. The method includes: forming a composite glue layer on a carrier substrate, in which the composite glue layer includes an ultraviolet glue and a photolysis material therein; placing an epi structure on the composite glue layer, the epi structure including at least an epitaxial layer and a metal layer, the metal layer being in contact with and attached to the composite glue layer, in which the epitaxial layer is present on a surface of the metal layer opposite to the composite glue layer; and irradiating the composite glue layer with ultraviolet light to generate a gas from the composite glue layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a cross-sectional view of a detachable bonding structure according to some embodiments of the present disclosure;

FIG. 2 is a schematic cross-sectional view of a device according to some embodiments of the present disclosure;

FIG. 3 is a schematic flow chart of a method of forming the detachable bonding structure according to some embodiments of the present disclosure;

FIG. 4A is a schematic view of an intermediate stage of the method of forming the detachable bonding structure according to some embodiments of the present disclosure;

FIG. 4B is a schematic view of an intermediate stage of the method of forming the detachable bonding structure according to some embodiments of the present disclosure;

FIG. 4C is a schematic view of an intermediate stage of the method of forming the detachable bonding structure according to some embodiments of the present disclosure;

FIG. 5A is a schematic view of an intermediate stage of the method of forming the detachable bonding structure according to some embodiments of the present disclosure;

FIG. 5B is a schematic view of an intermediate stage of the method of forming the detachable bonding structure according to some embodiments of the present disclosure;

FIG. 5C is a schematic view of an intermediate stage of the method of forming the detachable bonding structure according to some embodiments of the present disclosure;

FIG. 5D is a schematic view of an intermediate stage of the method of forming the detachable bonding structure according to some embodiments of the present disclosure;

FIG. 5E is a schematic view of an operation after the method of forming the detachable bonding structure according to some embodiments of the present disclosure; and

FIG. 6 is a schematic cross-sectional view of an epitaxial layer according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment”, “some embodiments” or the like means that a particular feature, structure, configuration, or characteristic described in connection with the embodiment is included in at least one embodiment of the disclosure. Thus, the appearances of the phrase “in one embodiment,” “in an embodiment”, “in some embodiments” or the like in various places throughout this specification are not necessarily referring to the same embodiment of the disclosure. Furthermore, the particular features, structures, configurations, or characteristics may be combined in any suitable manner in one or more embodiments.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

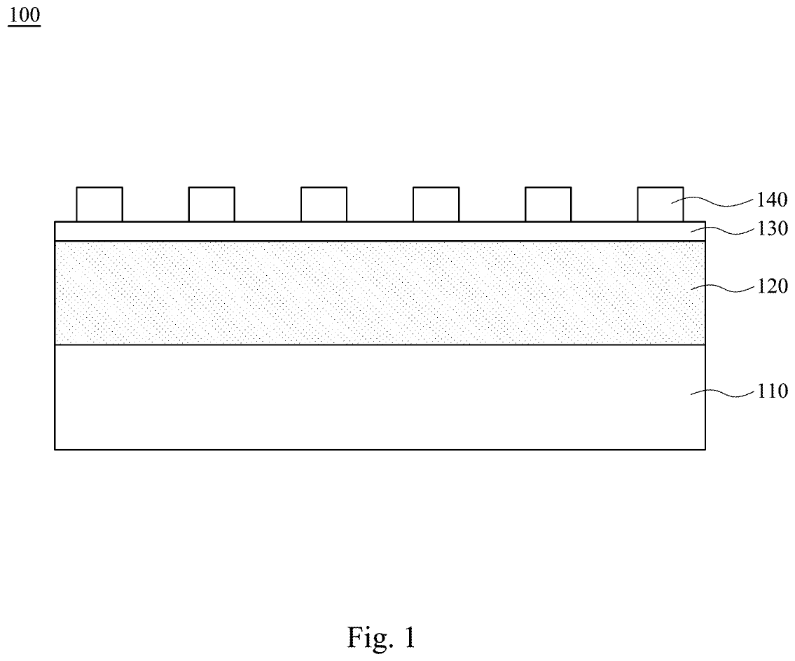

Reference is made to FIG. 1. FIG. 1 is a cross-sectional view of a detachable bonding structure 100 according to some embodiments of the present disclosure. In some embodiments, the detachable bonding structure 100 includes a carrier substrate 110, a composite glue layer 120, a metal layer 130, and a device 140 (or a plurality of the devices 140). The composite glue layer 120 is present on the carrier substrate 110. The composite glue layer 120 includes an ultraviolet glue and a photolysis material therein. The ultraviolet glue and the photolysis material are not explicitly labeled with reference numbers since they are mixed and without explicit boundaries in an ideal case. The metal layer 130 is present on the composite glue layer 120. The device 140 is present on the metal layer 130. In some embodiments, the photolysis material includes diazonaphthoquinone (DNQ) derivatives, which generates nitrogen (N₂) after being irradiated by visible light or ultraviolet (UV) light. The DNQ derivatives can include diazonaphthoquinone (DNQ), 4-Diazobenzo-2,5-cyclohexadienone, 3-Diazo-4-hydroxy-3,4-dihydronaphthalene-1-sulfonyl chloride, 5-chlorosulfonyl-2-diazonionaphthalen-1-olate, 2-diazo-1-naphthol-5-sulfonic acid sodium salt, or the like, and preferably DNQ. In some embodiments, the photolysis material includes organic peroxides, which generates oxygen (O2) after being irradiated by visible light or UV light. The organic peroxides can include dibenzoyl peroxide (BPO), 2,4-dichlorobenzoyl peroxide, diacetyl peroxide, di-n-octanoyl peroxide, dilauroyl peroxide, dicumyl peroxide (DCP), di-t-butyl peroxide (DTBP), tert-butyl peroxybenzoate (DCP), tert-butyl peroxypivalate (BPP), cumyl hydroperoxide (CHP), tert-butylhydroperoxide (TBP), diisopropyl peroxydicarbonate (IPP), di-sec-butyl peroxydicarbonate (IBP), dicyclohexyl peroxydicarbonate (DCPD), Bis(4-tert-butylcyclohexyl) peroxydicarbonate (TBCP), methyl ethyl ketone peroxide, cyclohexanone peroxide, 2,2-bis(tert-butylperoxy)butane (DBPB), or the like, and preferably dibenzoyl peroxide (BPO). In some embodiments, the photolysis material includes carbonyl compounds which take a Norrish type I reaction (alpha-cleavage) and generates isopropyl alcohol (IPA) after being irradiated by visible light or UV light. IPA is a high vapor pressure organic compound in the embodiments. The alpha-cleavage can include 2-hydroxy-2-methyl-phenyl-propane-1-one, 2-hydroxy-1-{4-[4-(2-hydroxyl-2-methyl-propionyl)-benzyl]-phenyl}-2-methyl-pro pan-1-one, 2-hydroxy-4′-(2-hydroxyethoxy)-2-methylpropiophenone, or the like, and preferably the 2-hydroxy-2-methyl-phenyl-propane-1-one. In some embodiments, the photolysis material includes AZO compounds, which generates N₂ after being irradiated by visible light or UV light. The Azo compounds can include 2,2′-azobis(isobutyronitrile) (AIBN), 2,2′-azobis(2,4-dimethylvaleronitrile), dimethyl 2,2′-azobis(2-methylpropionate), 2,2′-azobis(2-methylbutyronitrile), 1,1′-azobis(cyclohexane-1-carbonitrile), 2,2′-azobis(N-butyl-2-methylpropionamide), 2,2′-azobis(2,4,4-trimethylpentane), 2,2′-azobis(N-cyclohexyl-2-methylpropionamide), 2,2′-Azobis(2,4,4-trimethylpentane), or the like, and preferably the 2,2′-azobis(isobutyronitrile) (AIBN).

The detachable bonding structure 100 as disclosed in the above embodiments has at least a benefit on changeable stickiness of the composite glue layer 120. When a strong adhesion between the device 140 and the carrier substrate 110 is required in a manufacturing process (e.g., a chipping process for getting the plurality of devices 140 which will be described later in the present disclosure), said composite glue layer 120 is qualified for a strong stickiness. When a weak adhesion between the device 140 and the carrier substrate 110 is required in a manufacturing process (e.g., a transfer process for one or more devices 140 which will be described later in the present disclosure), the composite glue layer 120 is also qualified for a weak stickiness with a simple physical stimulation applied thereon, such as visible light or UV light irradiation.

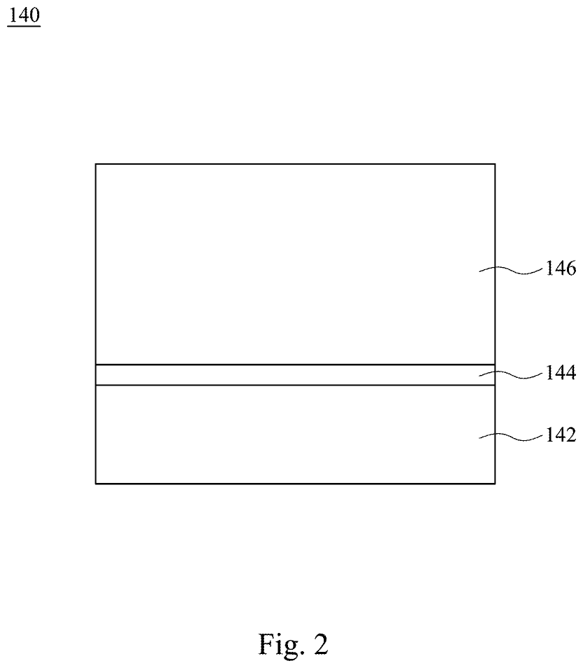

Reference is made to FIG. 2. FIG. 2 is a schematic cross-sectional view of the device 140 according to some embodiments of the present disclosure. In some embodiments, the device 140 includes a first type semiconductor layer 142, an active layer 144, and a second type semiconductor layer 146. The active layer 144 is present on the first type semiconductor layer 142. The second type semiconductor 146 layer is joined with the first type semiconductor layer 142 through the active layer 144. In some embodiments, the first type semiconductor layer 142 is a p-type semiconductor layer, but should not be limited thereto. In some embodiments, the second type semiconductor layer 146 is an n-type semiconductor layer, but should not be limited thereto.

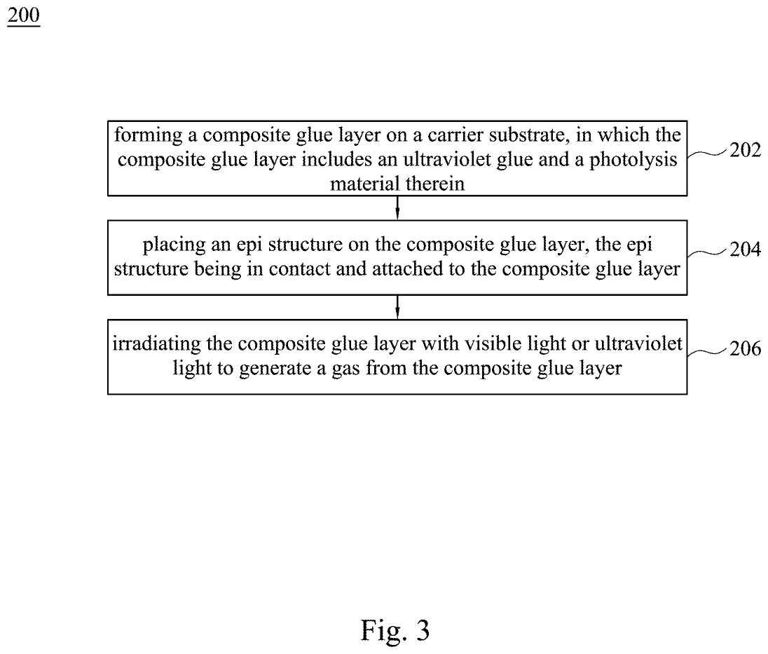

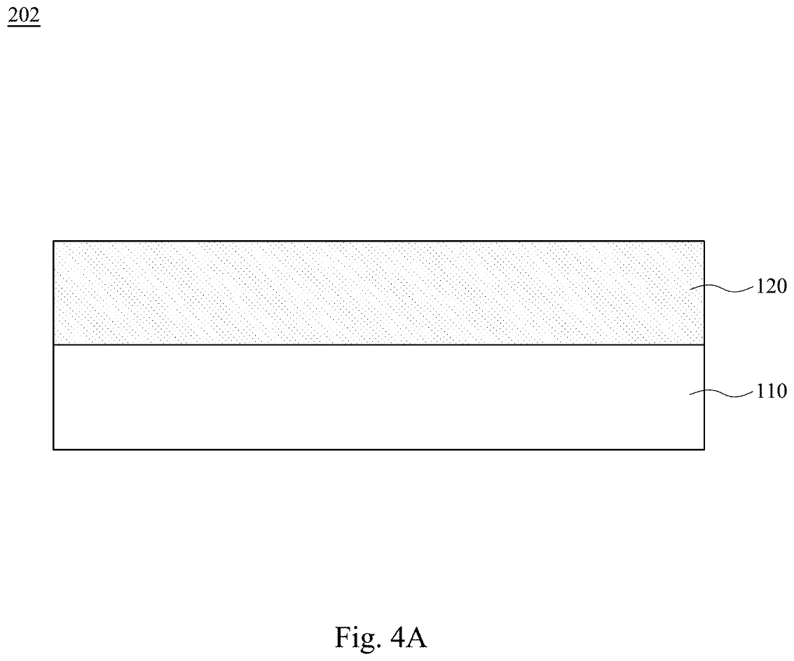

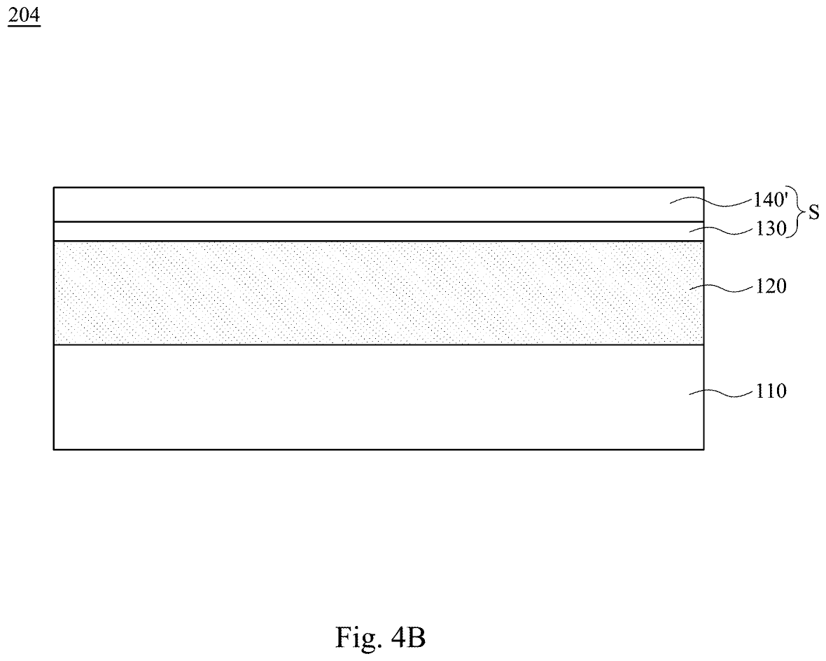

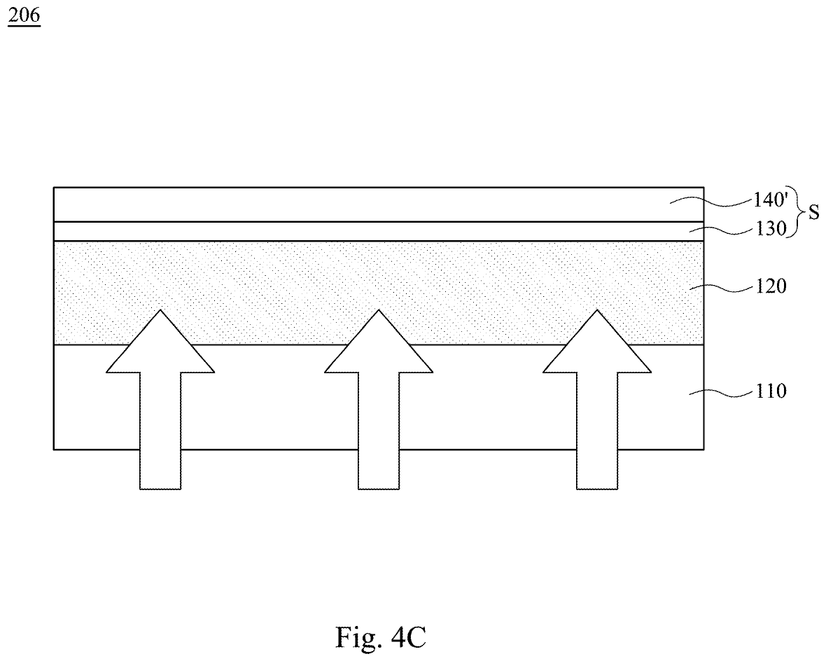

Reference is made to FIG. 3 and FIGS. 4A to 4C. FIG. 3 is a schematic flow chart of a method 200 of forming the detachable bonding structure 100 according to some embodiments of the present disclosure. FIGS. 4A to 4C are schematic views of intermediate stages of the method 200 according to some embodiments of the present disclosure. In some embodiments, the method 200 of forming the detachable bonding structure 100 for performing a device picked-up operation is provided. The method 200 begins with an operation 202 in which a composite glue layer 120 is formed on a carrier substrate 110 (also referred to FIG. 4A). The method 200 continues with an operation 204 in which an epi structure S is placed on the composite glue layer 120 (also referred to FIG. 4B). The method 200 continues with an operation 206 in which the composite glue layer 120 is irradiated with ultraviolet light to generate gas from the composite glue layer 120 (also referred to FIG. 4C).

Reference is made to FIG. 4A. The composite glue layer 120 formed on the carrier substrate 110 includes the ultraviolet glue and the photolysis material therein. Selected compounds for the photolysis material are substantially the same as the compounds shown in some embodiments mentioned above, and will not be repeated again herein. The formation of the composite glue layer 120 on the carrier substrate may include the following steps. The ultraviolet glue and the photolysis material are stirred, mixed together, and then spin coated or slit coated onto the carrier substrate 110. The carrier substrate 110 is then baked by a hot plate by about 10 minutes with a baking temperature from about 90 to 120 degree Celsius.

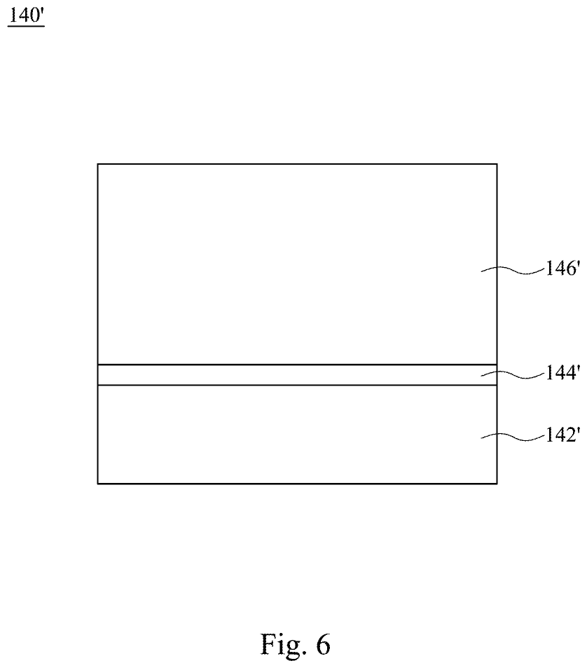

Reference is made to FIGS. 4B and 6. FIG. 6 is a schematic cross-sectional view of the epitaxial layer 140′ according to some embodiments of the present disclosure. The epi structure S placed on the composite glue layer 120 includes at least an epitaxial layer 140′ and the metal layer 130. The metal layer 130 is in contact with and attached to the composite glue layer 120. The epitaxial layer 140′ is present on a surface of the metal layer 130 opposite to the composite glue layer 120. In some embodiments, the epitaxial layer 140′ includes a first type semiconductor layer 142′, an active layer 144′, and a second type semiconductor layer 146′. The active layer 144′ is present on the first type semiconductor layer 142′. The second type semiconductor 146′ layer is joined with the first type semiconductor layer 142′ through the active layer 144′. In some embodiments the first type semiconductor layer 142′ is present on a surface of the metal layer 130 opposite to the composite glue layer 120. In some embodiments, the first type semiconductor layer 142′ is a p-type semiconductor layer, but should not be limited thereto. In some embodiments, the second type semiconductor layer 146′ is an n-type semiconductor layer, but should not be limited thereto.

Reference is made to FIG. 4C. In some embodiments, when the composite glue layer 120 is irradiated with the ultraviolet light, the gas generated from the composite glue layer 120 can include N₂, O₂, IPA, or combinations thereof, but should not be limited thereto. N₂ may be generated when the photolysis material within the composite glue layer 120 include diazonaphthoquinone (DNQ) dervatives or Azo compounds (e.g., 2,2′-Azobis(isobutyronitrile) AIBN), but should not be limited thereto. O₂ may be generated when the photolysis material within the composite glue layer 120 include organic peroxide(e.g., dibenzoyl peroxide (BPO)), but should not be limited thereto. IPA may be generated when the photolysis material within the composite glue layer 120 include carbonyl compounds which take a Norrish type I reaction (alpha-cleavage) (e.g., 2-Hydroxy-2-methyl-phenyl-propane-1-one), but should not be limited thereto. After the gas generation, the stickiness of the composite glue layer 120 is reduced such that subsequent processes for the epitaxial layer 140′ are becoming easier to be performed. In some embodiments, one of the subsequent processes is to pick up or detach (a portion of) a combination of the epitaxial layer 140′ and the metal layer 130 from the composite glue layer 120.

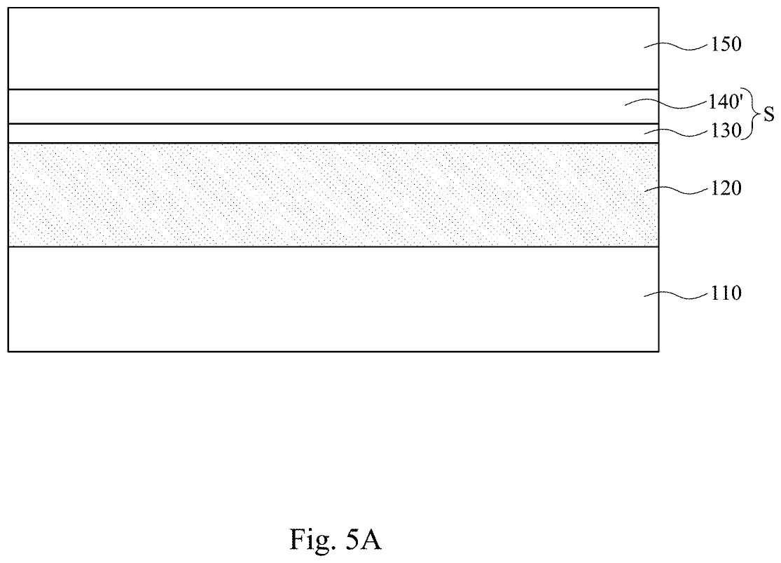

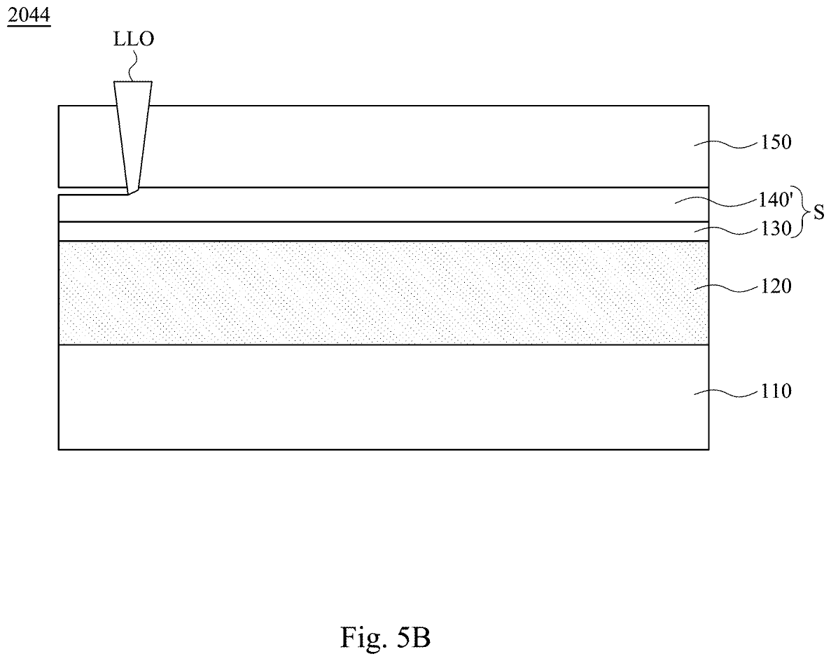

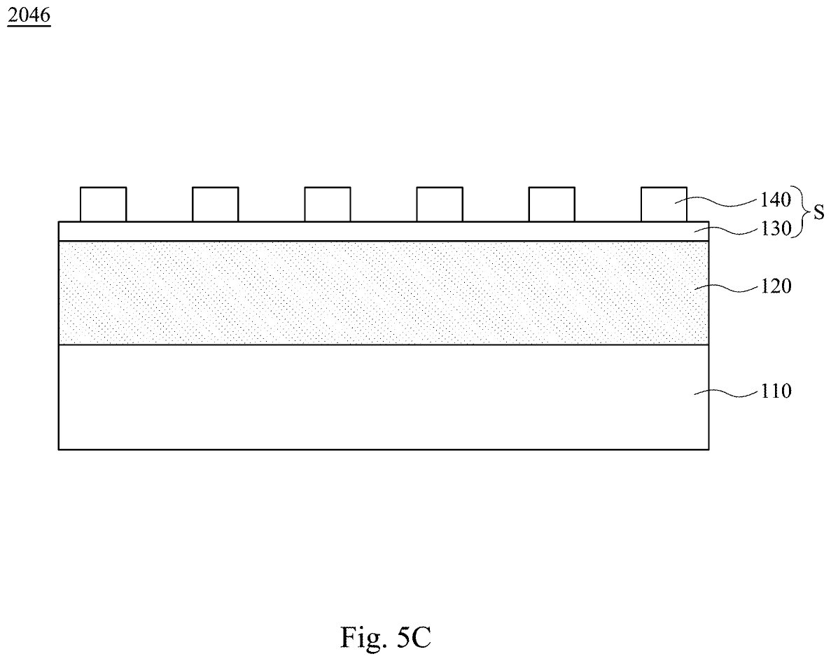

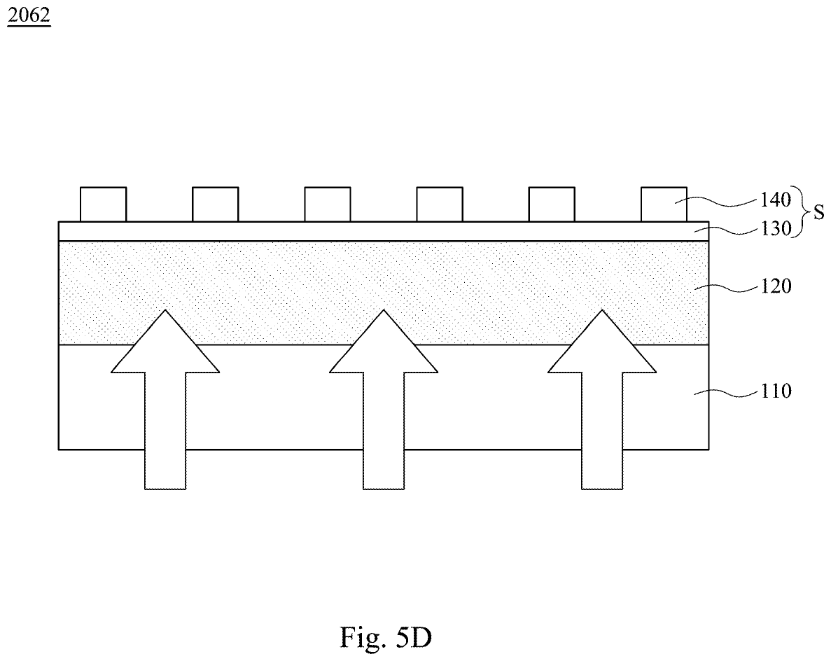

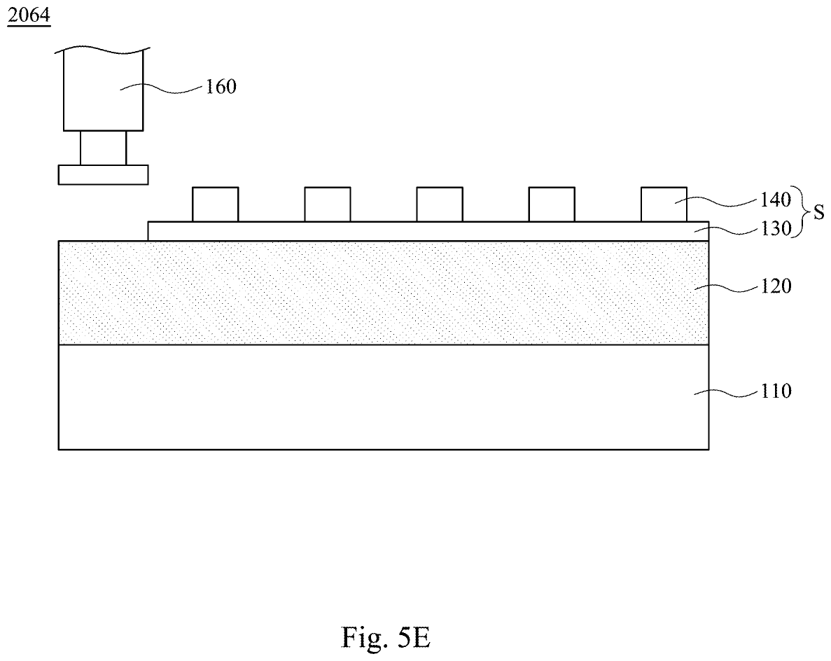

Reference is made to FIGS. 5A to 5E. FIGS. 5A to 5D are schematic views of intermediate stages of the method 200 according to some embodiments of the present disclosure. FIG. 5E is a schematic view of an operation after the method 200 according to some embodiments of the present disclosure. In some embodiments, a growth substrate 150 is further present on a surface of the epitaxial layer 140′ opposite to the metal layer 130 (also referred to FIG. 5A). The growth substrate 150 is used to grow the epitaxial layer 140′ before said placing (i.e. the operation 204) is performed. In some embodiments, the method 200 further includes an operation 2044 in which a laser lift-off process LLO is performed to separate the growth substrate 150 from the epitaxial layer 140′ before the composite glue layer 120 is irradiated with the ultraviolet light (also referred to FIG. 5B). In some embodiments, the method 200 further includes an operation 2046 in which the epitaxial layer 140′ is chipped to form a plurality of devices 140 before irradiating the composite glue layer 120 with the ultraviolet light (also referred to FIG. 5C). After the chipping, the composite glue layer 120 is irradiated with the ultraviolet light, such that the gas (e.g., N₂, O₂, and/or IPA) is generated from the composite glue layer 120 (also referred to FIG. 5D). After the irradiation, one or more of the devices 140 with a part of the metal layer 130 underlying said one or more of the devices 140 can be picked up more easily without disturbing or destroying neighboring structures. One method for picking up said one or more of the devices 140 is using a transfer head 160 to adhere or to electrically attract said one or more of the devices 140 as shown in FIG. 5E, but should not be limited thereto. The reason why the picking-up can be easier is that the gas generated can reduce a pressure difference between a pick-up interface and the atmospheric pressure. Said pick-up interface is an interface between the metal layer 130 and the composite glue layer 120. It should be noted that, normally in conventional understandings, it is not preferred to mix the photolysis material with the ultraviolet glue, especially when the ultraviolet glue is adopted to attach an object. The reason is that the photolysis material may reduce a stickiness/viscosity of the ultraviolet glue. However, in some embodiments of the present disclosure, it is found that a mixture of the photolysis material and the ultraviolet glue (i.e., the composite glue layer 120) is not only able to attach the epitaxial layer 140′ well during said chipping, but also facilitate easier picking up of the device 140 from the composite glue layer 120 after the composite glue layer 120 is irradiated with visible light or UV light.

In summary, the embodiments of the present disclosure provide a detachable bonding structure having a composite glue layer in which a stickiness thereof is changeable, which can greatly facilitate manufacturing processes, such as forming and transferring micro devices in the detachable bonding structure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

1. A detachable bonding structure for performing a device picked-up operation, comprising:
a carrier substrate;
a composite glue layer present on the carrier substrate, the composite glue layer comprising an ultraviolet glue and a photolysis material therein;
a metal layer present on the composite glue layer; and
a device present on the metal layer.

2. The detachable bonding structure of claim 1, wherein the device comprises:
a first type semiconductor layer;
an active layer present on the first type semiconductor layer; and
a second type semiconductor layer joined with the first type semiconductor layer through the active layer.

3. The detachable bonding structure of claim 1, wherein the photolysis material comprises diazonaphthoquinone (DNQ) derivatives.

4. The detachable bonding structure of claim 1, wherein the photolysis material comprises carbonyl compounds which take a Norrish type I reaction (alpha-cleavage).

5. The detachable bonding structure of claim 1, wherein the photolysis material comprises Azo compounds.

6. The detachable bonding structure of claim 1, wherein the photolysis material comprises organic peroxides.

7. A method of forming a detachable bonding structure for performing a device picked-up operation, comprising:
forming a composite glue layer on a carrier substrate, wherein the composite glue layer comprises an ultraviolet glue and a photolysis material therein;
placing an epi structure on the composite glue layer, the epi structure comprising at least an epitaxial layer and a metal layer, the metal layer being in contact and attached to the composite glue layer, wherein the epitaxial layer is present on a surface of the metal layer opposite to the composite glue layer; and
irradiating the composite glue layer with visible light or ultraviolet light to generate a gas from the composite glue layer.

8. The method of claim 7, wherein the epitaxial layer comprises:
a first type semiconductor layer;
an active layer present on the first type semiconductor layer; and
a second type semiconductor layer joined with the first type semiconductor layer through the active layer.

9. The method of claim 7, wherein the photolysis material comprises diazonaphthoquinone (DNQ) derivatives.

10. The method of claim 7, wherein the photolysis material comprises carbonyl compounds which take a Norrish type I reaction (alpha-cleavage).

11. The method of claim 7, wherein the photolysis material comprises Azo compounds.

12. The method of claim 7, wherein the photolysis material comprises organic peroxides.

13. The method of claim 7, further comprising chipping the epitaxial layer to form a plurality of devices before irradiating the composite glue layer with the ultraviolet light.

14. The method of claim 7, further comprising a growth substrate present on a surface of the epitaxial layer opposite to the metal layer.

15. The method of claim 14, further comprising performing a laser lift-off process to separate the growth substrate from the epitaxial layer before irradiating the composite glue layer with the ultraviolet light.
